(19) United States
(12) Patent Application Publication
(10) Pub. No.: US 2015/0280646 A1
(43) Pub. Date: Oct. 1, 2015

(54) OSCILLATION CIRCUIT, OSCILLATOR, ELECTRONIC APPARATUS, MOVING OBJECT, AND CONTROL METHOD OF OSCILLATOR

(71) Applicant: Seiko Epson Corporation, Tokyo (JP)

(72) Inventors: Toru WATANABE, Matsumoto (JP); Yoshihiko NIMURA, Hara (JP)

(21) Appl. No.: 14/674,044

(22) Filed: Mar. 31, 2015

(30) Foreign Application Priority Data
Apr. 1, 2014 (JP) 2014-075468

(51) Int. Cl. H03B 5/30; B81B 7/00

(52) U.S. Cl. CPC H03B 5/30; B81B 7/008; B81B 2207/03

(57) ABSTRACT

An oscillation circuit is configured to include a voltage generating unit that includes a booster circuit operating in response to the supply of a pulse signal, and boosts an input reference voltage to generate a bias voltage and outputs the bias voltage to a vibrator; a clock pulse signal generating unit that generates and outputs a clock pulse signal; and a switch unit that switches its state between a first state in which the pulse signal to be input to the booster circuit is set to the clock pulse signal and a second state in which the pulse signal is set to a signal oscillated from the vibrator.

### BACKGROUND

1. Technical Field

The present invention relates to an oscillation circuit, an oscillator, an electronic apparatus, a moving object, and a control method of an oscillator.

2. Related Art

Oscillators using electrostatic capacitive vibrators such as MEMS (Micro Electro Mechanical Systems) vibrators have been developed. As an example of MEMS vibrators, there is a MEMS vibrator including a fixed electrode and a movable electrode, in which the movable electrode is driven with an electrostatic force occurring between the electrodes. When such a vibrator is used in an oscillator, a bias voltage is generally applied between the electrodes.

JP-A-2010-232792 discloses an oscillator in which a booster circuit for applying a bias voltage to a vibrator is operated with a clock pulse whose oscillation source is the vibrator.

It is necessary for the oscillator disclosed in JP-A-2010-232792 to oscillate such that the vibrator and an oscillation circuit satisfy oscillation conditions before the booster circuit performs a boosting operation. However, when, for example, a voltage to be supplied to the oscillator is lowered, it is difficult to satisfy the oscillation conditions. For this reason, when the oscillation conditions cannot be satisfied because of variations in the manufacture of the vibrator, or the like, there is a possibility of failing to perform a desired oscillating operation.

### SUMMARY

An advantage of some aspects of the invention is to provide an oscillation circuit capable of performing an oscillating operation even with a low voltage, an oscillator, an electronic apparatus, a moving object, and a control method of an oscillator.

The invention can be implemented as the following forms or application examples.

### Application Example 1

An oscillation circuit according to this application example includes: a voltage generating unit that includes a booster circuit operating in response to the supply of a pulse signal, and boosts an input reference voltage to generate a bias voltage and outputs the bias voltage to a vibrator; a clock pulse signal generating unit that generates and outputs a clock pulse signal; and a switch unit that switches its state between a first state in which the pulse signal to be input to the booster circuit is set to the clock pulse signal and a second state in which the pulse signal is set to a signal oscillated from the vibrator.

According to this application example, since the booster circuit is operated with the clock pulse signal in the first state, the booster circuit can be operated even with a low voltage to generate the bias voltage. Hence, it is possible to realize the oscillation circuit capable of performing an oscillating operation even with a low voltage. Moreover, since the booster circuit is operated with the signal oscillated from the vibrator in the second state, degradation of an output signal caused by intermodulation distortion can be suppressed.

### Application Example 2

In the oscillation circuit described above, the clock pulse signal generating unit may stop outputting the clock pulse signal when the switch unit is in the second state.

With this configuration, the degradation of the output signal caused by the intermodulation distortion can be further suppressed.

### Application Example 3

In the oscillation circuit described above, the switch unit may switch the state from the first state to the second state.

With this configuration, after performing an oscillating operation by operating the booster circuit with the clock pulse signal, the booster circuit is operated with the oscillation signal whose oscillation source is the vibrator. Therefore, the degradation of the output signal caused by the intermodulation distortion can be suppressed.

### Application Example 4

In the oscillation circuit described above, the switch unit may be in the first state upon initial energization.

With this configuration, an oscillating operation can be performed by operating the booster circuit with the clock pulse signal upon initial energization. Hence, it is possible to realize the oscillation circuit capable of performing an oscillating operation even with a low voltage.

### Application Example 5

In the oscillation circuit described above, the switch unit may switch the state from the first state to the second state when the voltage amplitude of the oscillation signal is equal to or greater than a reference value.

With this configuration, the state can be switched from the first state to the second state after performing a proper oscillating operation.

### Application Example 6

In the oscillation circuit described above, the switch unit may switch the state from the first state to the second state when an elapsed time since initial energization is equal to or greater than a reference time.

With this configuration, the state can be switched from the first state to the second state after performing a proper oscillating operation.

### Application Example 7

In the oscillation circuit described above, the oscillation circuit may further include a frequency dividing circuit that divides the frequency of a signal whose oscillation source is the vibrator to output the oscillation signal.

With this configuration, it is easy to generate the oscillation signal at a frequency suitable for the operation of the booster circuit.

### Application Example 8

In the oscillation circuit described above, the voltage generating unit may include a voltage adjusting circuit that converts an input or output voltage of the booster circuit into a voltage having a given magnitude and outputs the voltage.

With this configuration, it is easy to generate the bias voltage suitable for the operation of the vibrator.

### Application Example 9

In the oscillation circuit described above, the vibrator may be an electrostatic capacitive MEMS vibrator.

With this configuration, it is possible to realize the oscillation circuit suitable for the driving of an electrostatic capacitive MEMS vibrator.

### Application Example 10

An oscillator according to this application example includes: any of the oscillation circuits described above; and the vibrator.

### Application Example 11

An electronic apparatus according to this application example includes any of the oscillation circuits described above.

### Application Example 12

A moving object according to this application example includes any of the oscillation circuits described above.

According to these oscillator, electronic apparatus, and moving object, since the oscillation circuit capable of performing an oscillating operation even with a low voltage is included, it is possible to realize the oscillator, electronic apparatus, and moving object capable of performing a proper operation even with a low voltage.

### Application Example 13

A control method of an oscillator according to this application example includes: boosting, in response to the supply of a clock pulse signal, an input reference voltage to generate a bias voltage and outputting the bias voltage to a vibrator; and boosting, in response to the supply of a signal oscillated from the vibrator, the reference voltage to generate the bias voltage and outputting the bias voltage to the vibrator.

According to this application example, since the reference voltage can be boosted with the clock pulse signal to generate the bias voltage in the boosting of the reference voltage with the clock pulse signal, it is possible to realize the control method of an oscillator capable of performing an oscillating operation even with a low voltage. Moreover, since the reference voltage can be boosted with the oscillation signal whose oscillation source is the vibrator to generate the bias voltage in the boosting of the reference voltage with the oscillation signal, the degradation of the output signal caused by the intermodulation distortion can be suppressed.

### BRIEF DESCRIPTION OF THE DRAWINGS

The invention will be described with reference to the accompanying drawings, wherein like numbers reference like elements.

FIG. 1 is a circuit diagram of an oscillation circuit according to a first embodiment.

FIG. 2 is a circuit diagram of a voltage generating unit.

FIG. 3 is a circuit diagram of an active unit.

FIG. 4 is a circuit diagram of a control unit.

FIG. 5 is a circuit diagram of an oscillation circuit according to a second embodiment.

FIG. 6 is a circuit diagram of a voltage generating unit according to a third embodiment.

FIG. 7 is a circuit diagram of a voltage generating unit according to a fourth embodiment.

FIG. 8 is a circuit diagram of an oscillator according to an embodiment.

FIG. 9 is a plan view schematically showing a configuration example of a vibrator.

FIG. 10 is a cross-sectional view schematically showing the configuration example of the vibrator.

FIG. 11 is a flowchart showing a control method of an oscillator according to an embodiment.

FIG. 12 is a functional block diagram of an electronic apparatus according to an embodiment.

FIG. 13A is a diagram showing an example of the appearance of a smartphone as an example of the electronic apparatus; and FIG. 13B shows a wrist-worn portable device as an example of the electronic apparatus.

FIG. 14 is a diagram (top view) showing an example of a moving object according to an embodiment.

### DESCRIPTION OF EXEMPLARY EMBODIMENTS

Hereinafter, preferred embodiments of the invention will be described in detail with reference to the drawings. The drawings referred to are provided for convenience of description. The embodiments described below do not unduly limit the contents of the invention set forth in the appended claims. Moreover, not all of the configurations described below are indispensable configuration requirements of the invention.

### 1. Oscillation Circuit

### 1-1. First Embodiment

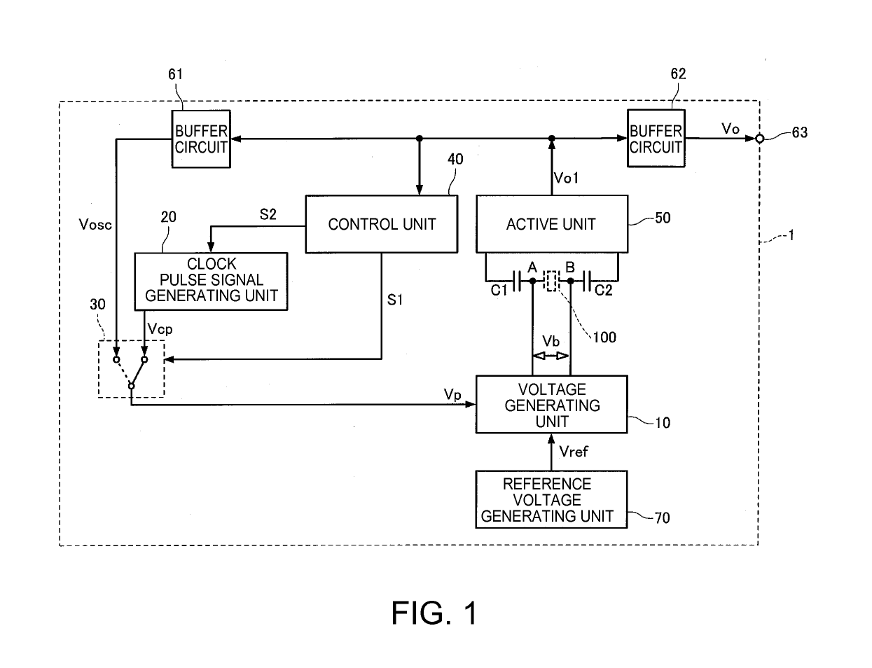

FIG. 1 is a circuit diagram of an oscillation circuit 1 according to a first embodiment.

The oscillation circuit 1 according to the embodiment is configured to include a voltage generating unit 10 that includes a booster circuit 11 operating in response to the supply of a pulse signal Vp, and boosts an input reference voltage Vref to generate a bias voltage Vb and outputs the bias voltage Vb to a vibrator 100, a clock pulse signal generating unit 20 that generates and outputs a clock pulse signal Vcp, and a switch unit 30 that switches its state between a first state in which the pulse signal Vp to be input to the booster circuit 11 is set to the clock pulse signal Vcp and a second state in which the pulse signal Vp is set to a signal (oscillation signal whose oscillation source is the vibrator 100) Vosc oscillated from the vibrator 100.

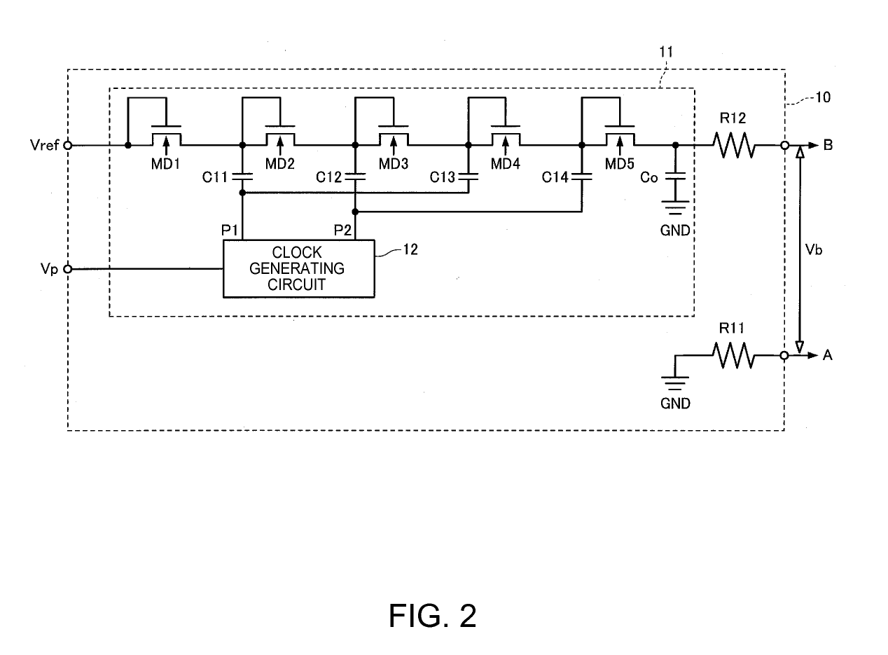

FIG. 2 is a circuit diagram of the voltage generating unit 10. The voltage generating unit 10 generates the bias voltage Vb necessary for operating the vibrator 100 as an oscillation source. In the example shown in FIG. 2, the voltage generating unit 10 is configured to include the booster circuit 11, a resistor R11, and a resistor R12.

The booster circuit 11 is composed of a so-called Dickson charge pump circuit. In the example shown in FIG. 2, the booster circuit 11 is configured to include a clock generating circuit 12, a switch element MD1, a switch element MD2, a switch element MD3, a switch element MD4, a switch element MD5, a capacitor C11, a capacitor C12, a capacitor C13, a capacitor C14, and a capacitor Co.

The clock generating circuit 12 generates, using the pulse signal Vp, a positive phase clock pulse P1 having the same frequency and phase as those of the pulse signal Vp, and a negative phase clock pulse P2 that is the same as the positive phase clock pulse P1 excepting that the phase is inverted from the pulse signal Vp.

The booster circuit 11 boosts, using the positive phase clock pulse P1 and the negative phase clock pulse P2 that are generated by the clock generating circuit 12, the input reference voltage Vref to output the bias voltage Vb higher than the reference voltage Vref.

The booster circuit 11 includes the five switch elements MD1, MD2, MD3, MD4, and MD5 that are connected in series, the four capacitors C11, C12, C13, and C14 whose one ends are connected to connecting points of the switch elements MD1 to MD5, and the capacitor Co whose one end is connected to the output side of the switch element MD5 at the final stage of the switch elements MD1 to MD5. The switch element MD1 to the switch element MD5 are composed of diode-connected NMOS transistors. The other ends of the capacitor C11 and the capacitor C13 are connected with the clock generating circuit 12 so that the positive phase clock pulse P1 is input to the capacitor C11 and the capacitor C13. The other ends of the capacitor C12 and the capacitor C14 are connected with the clock generating circuit 12 so that the negative phase clock pulse P2 is input to the capacitor C12 and the capacitor C14.

The voltage generating unit 10 connects a node A that is electrically connected with a first terminal of the vibrator 100 with a ground potential GND via the resistor R11. The reference voltage Vref that is boosted by the booster circuit 11 is input from one end (input side) of the switch element MD1, and the boosted bias voltage Vb is output from the other end (output side) of the switch element MD5 via the resistor R12 to a node B that is electrically connected with a second terminal of the vibrator 100.

In the booster circuit 11, when the positive phase clock pulse P1 is at a low level and the negative phase clock pulse P2 is at a high level, the potential at the other ends of the capacitor C11 and the capacitor C13 is at the low level and the potential at the other ends of the capacitor C12 and the capacitor C14 is at the high level. Therefore, the switch element MD1, the switch element MD3, and the switch element MD5 are brought into a conductive state while the switch element MD2 and the switch element MD4 are brought into a cut-off state.

Moreover, in the booster circuit 11, when the positive phase clock pulse P1 is at the high level and the negative phase clock pulse P2 is at the low level, the potential at the other ends of the capacitor C12 and the capacitor C14 is at the low level and the potential at the other ends of the capacitor C11 and the capacitor C13 is at the high level. Therefore, the switch element MD2 and the switch element MD4 are brought into the conductive state while the switch element MD1, the switch element MD3, and the switch element MD5 are brought into the cut-off state.

With the switching operation of the switch element MD1 to the switch element MD5 and the charging and discharging operation of the capacitor C11 to the capacitor C14 and the capacitor Co, a voltage of 5×(Vref−Vth) obtained by subtracting a threshold voltage Vth of each of the switch elements MD from the reference voltage Vref is charged to the capacitor Co at the final stage. With this configuration, the voltage generating unit 10 outputs the bias voltage Vb of 5×(Vref−Vth) between the node A and the node B.

Referring back to FIG. 1, the clock pulse signal generating unit 20 generates the clock pulse signal Vcp and outputs the clock pulse signal Vcp to the switch unit 30. The clock pulse signal generating unit 20 may be configured to include, for example, various types of publicly known oscillation circuits such as a CR oscillation circuit. Moreover, the clock pulse signal generating unit 20 may be configured to further include, for example, a frequency dividing circuit that divides the frequency of an output signal of a CR oscillation circuit.

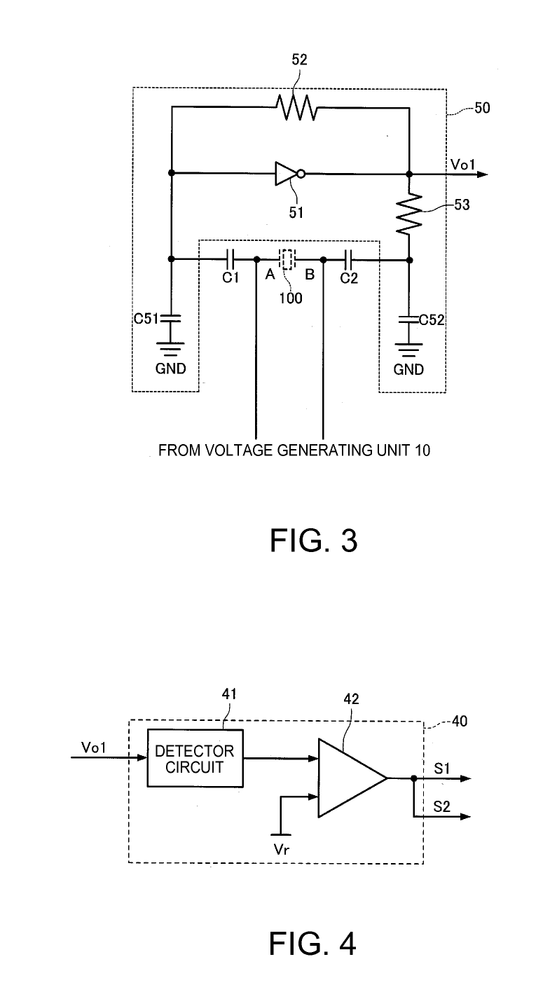

FIG. 3 is a circuit diagram of an active unit 50. The active unit 50 generates and outputs an oscillation signal Vo1 whose oscillation source is the vibrator 100. The active unit 50 is composed of a so-called inverter oscillation circuit. In the example shown in FIG. 3, the active unit 50 is configured to include an amplifier circuit 51, a resistor 52, a resistor 53, a capacitor C51, and a capacitor C52.

The amplifier circuit 51 is an inverting amplifier circuit whose input side is connected via a capacitor C1 with the node A (the first terminal side of the vibrator 100) and whose output side is connected via the resistor 53 and a capacitor C2 with the node B (the second terminal side of the vibrator 100). The input and output sides of the amplifier circuit 51 are connected via the resistor 52. Moreover, the input side of the amplifier circuit 51 is connected via the capacitor C51 to the ground potential GND. Moreover, the output side of the amplifier circuit 51 is connected via the resistor 53 and the capacitor C52 to the ground potential GND. The amplifier circuit 51 outputs the oscillation signal Vo1 whose oscillation source is the vibrator 100 from the output side.

Referring back to FIG. 1, the oscillation circuit 1 is configured to include a buffer circuit 61 and a buffer circuit 62. The buffer circuit 61 and the buffer circuit 62 are each composed of a buffer amplifier. The buffer circuit 61 receives the oscillation signal Vo1 output by the active unit 50, and outputs the oscillation signal Vosc whose oscillation source is the vibrator 100 to the switch unit 30. The buffer circuit 62 receives the oscillation signal Vo1 output by the active unit 50, and outputs an output signal Vo whose oscillation source is the vibrator 100 to an output terminal 63.

The switch unit 30 switches its state between the first state in which the pulse signal Vp to be input to the booster circuit 11 is set to the clock pulse signal Vcp and the second state in which the pulse signal Vp is set to the oscillation signal Vosc whose oscillation source is the vibrator 100. The switch unit 30 selects either the clock pulse signal Vcp or the oscillation signal Vosc and outputs the selected signal as the pulse signal Vp to the voltage generating unit 10. The switch unit 30 may be configured to include various types of publicly known switch elements such as a transistor.

According to the oscillation circuit 1 according to the embodiment, since the booster circuit 11 is operated with the clock pulse signal Vcp in the first state, the booster circuit 11 can be operated even with a low voltage to generate the bias voltage Vb. Hence, it is possible to realize the oscillation circuit 1 capable of performing an oscillating operation even with a low voltage. Moreover, since the booster circuit 11 is operated with the signal (oscillation signal whose oscillation source is the vibrator 100) Vosc oscillated from the vibrator 100 in the second state, degradation of the output signal Vo caused by intermodulation distortion of the clock pulse signal Vcp and the oscillation signal Vosc (and the oscillation signal Vo1) can be suppressed.

In the oscillation circuit 1 described above, the switch unit 30 may switch the state from the first state to the second state. That is, the switch unit 30 may be configured so as to be brought into the second state after the first state. With this configuration, after performing an oscillating operation by operating the booster circuit 11 with the clock pulse signal Vcp, the booster circuit 11 is operated with the oscillation signal Vosc whose oscillation source is the vibrator 100. Therefore, the degradation of the output signal Vo caused by the intermodulation distortion of the clock pulse signal Vcp and the oscillation signal Vosc (and the oscillation signal Vo1) can be suppressed.

In the oscillation circuit 1 described above, the switch unit 30 may be in the first state upon initial energization. With this configuration, an oscillating operation can be performed by operating the booster circuit 11 with the clock pulse signal Vcp upon initial energization. Hence, it is possible to realize the oscillation circuit 1 capable of performing an oscillating operation even with a low voltage.

In the oscillation circuit 1 described above, the switch unit 30 may switch the state from the first state to the second state when the voltage amplitude of the oscillation signal Vosc is equal to or greater than a reference value. Moreover, the switch unit 30 may switch the state from the first state to the second state when the voltage amplitude of the oscillation signal Vo1 is equal to or greater than the reference value. The reference value is any value that can be previously set.

In the example shown in FIG. 1, the oscillation circuit 1 is configured to include a control unit 40 that outputs a control signal S1 to the switch unit 30.

FIG. 4 is a circuit diagram of the control unit 40. In the example shown in FIG. 4, the control unit 40 is configured to include a detector circuit 41 and a comparator circuit 42.

The detector circuit 41 receives the oscillation signal Vo1, and outputs a voltage according to the magnitude of the oscillation signal Vo1 to the comparator circuit 42. The comparator circuit 42 outputs a result of comparison between the voltage output by the detector circuit 41 and a reference voltage Vr, as the control signal S1 of a high-level or low-level voltage.

According to the oscillation circuit 1 according to the embodiment as described above, the state can be switched from the first state to the second state after performing a proper oscillating operation with the vibrator 100 as an oscillation source.

The switch unit 30 may switch the state from the first state to the second state when an elapsed time since the initial energization is equal to or greater than a reference time. The time from the initial energization to the performing of a proper oscillating operation with the vibrator 100 as an oscillation source is roughly determined. Therefore, even with the configuration described above, the state can be switched from the first state to the second state after performing a proper oscillating operation with the vibrator 100 as an oscillation source.

In the oscillation circuit 1 described above, the clock pulse signal generating unit 20 may stop outputting the clock pulse signal Vcp when the switch unit 30 is in the second state. In the embodiment, the control unit 40 outputs a control signal S2 to the clock pulse signal generating unit 20 to thereby control the operation of the clock pulse signal generating unit 20 in synchronization with the switch unit 30. With this configuration, the degradation of the output signal Vo caused by the intermodulation distortion of the clock pulse signal Vcp and the oscillation signal Vosc (and the oscillation signal Vo1) can be further suppressed.

The vibrator 100 used together with the oscillation circuit 1 described above may be, for example, an electrostatic capacitive MEMS vibrator. With this configuration, it is possible to realize the oscillation circuit 1 suitable for the driving of an electrostatic capacitive MEMS vibrator.

### 1-2. Second Embodiment

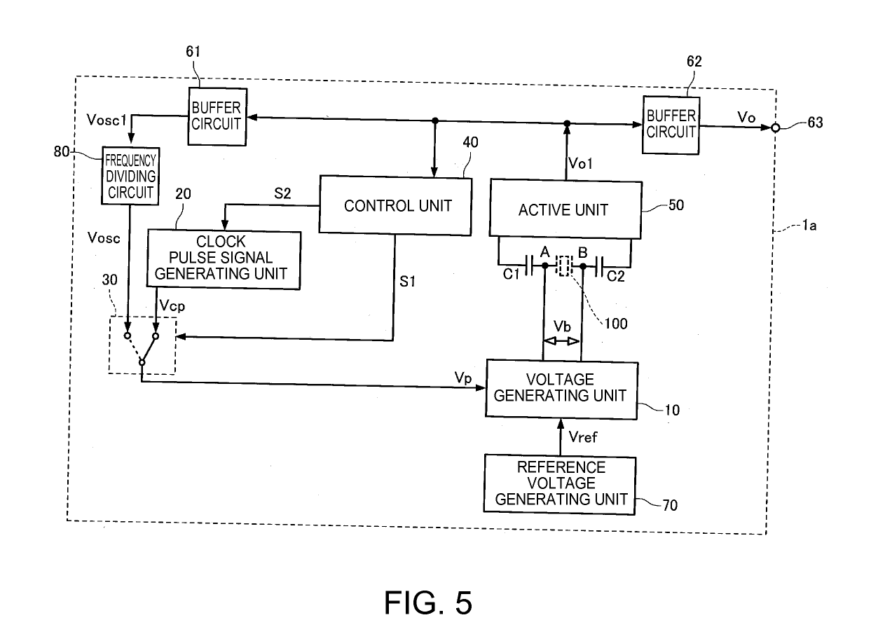

FIG. 5 is a circuit diagram of an oscillation circuit 1a according to a second embodiment. Configurations similar to those of the oscillation circuit 1 according to the first embodiment are denoted by the same reference signs and numerals, and a detailed description thereof is omitted.

The oscillation circuit 1a according to the embodiment is configured to include a frequency dividing circuit 80 that divides the frequency of a signal Vosc1 whose oscillation source is the vibrator 100, and outputs the oscillation signal Vosc. In the example shown in FIG. 5, the frequency dividing circuit 80 divides the frequency of the signal Vosc1 output by the buffer circuit 61, and outputs the oscillation signal Vosc to the switch unit 30.

According to the oscillation circuit 1a according to the embodiment, it is easy to generate the oscillation signal Vosc at a frequency suitable for the operation of the booster circuit 11.

Also in the oscillation circuit 1a according to the embodiment, advantageous effects similar to those of the oscillation circuit 1 according to the first embodiment are provided for reasons similar thereto.

### 1-3. Third Embodiment

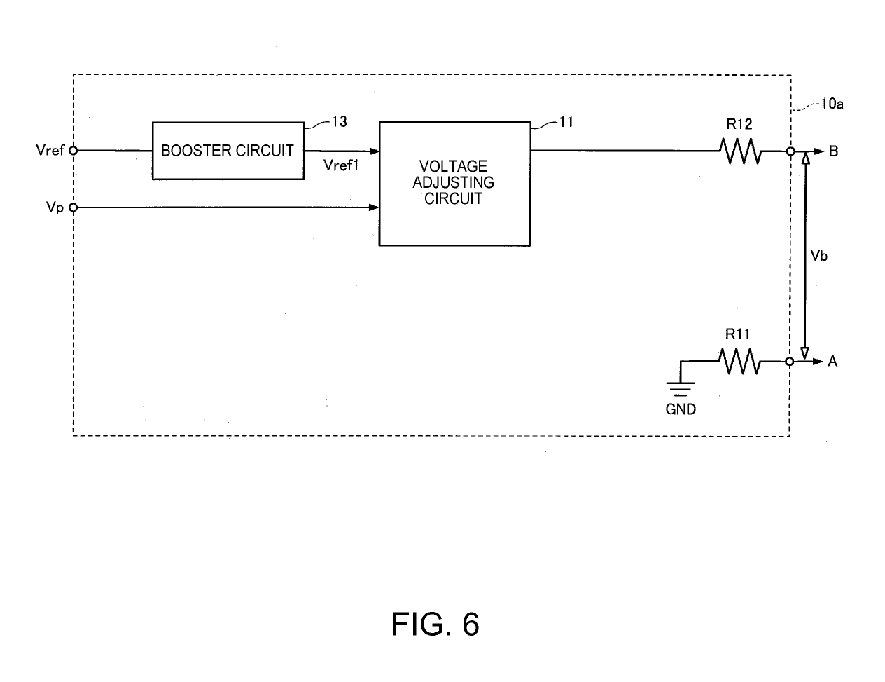

The voltage generating unit 10 in the oscillation circuit 1 and the oscillation circuit 1a described above can be variously modified. FIG. 6 is a circuit diagram of a voltage generating unit 10a according to a third embodiment.

The voltage generating unit 10a shown in FIG. 6 is configured to include a voltage adjusting circuit 13 that converts the reference voltage Vref serving as an input voltage of the booster circuit 11 into a voltage Vref1 having a given magnitude and outputs the voltage Vref1. The voltage adjusting circuit 13 may be configured to include, for example, a resistance voltage dividing circuit.

According to the embodiment, it is easy to generate the bias voltage Vb suitable for the operation of the vibrator 100.

### 1-4. Fourth Embodiment

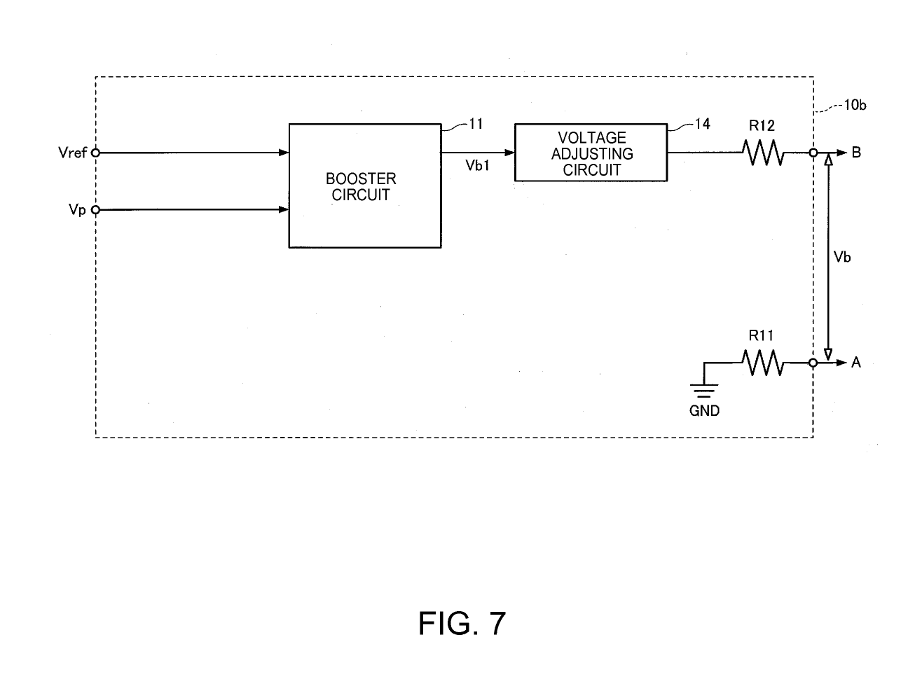

FIG. 7 is a circuit diagram of a voltage generating unit 10b according to a fourth embodiment.

The voltage generating unit 10b shown in FIG. 7 is configured to include a voltage adjusting circuit 14 that converts an output voltage Vb1 of the booster circuit 11 into a voltage having a given magnitude and outputs the voltage. The voltage adjusting circuit 14 may be configured to include, for example, a resistance voltage dividing circuit.

According to the embodiment, it is easy to generate the bias voltage Vb suitable for the operation of the vibrator 100.

### 2. Oscillator

An oscillator 1000 according to this embodiment is configured to include the oscillation circuit 1 and the vibrator 100.

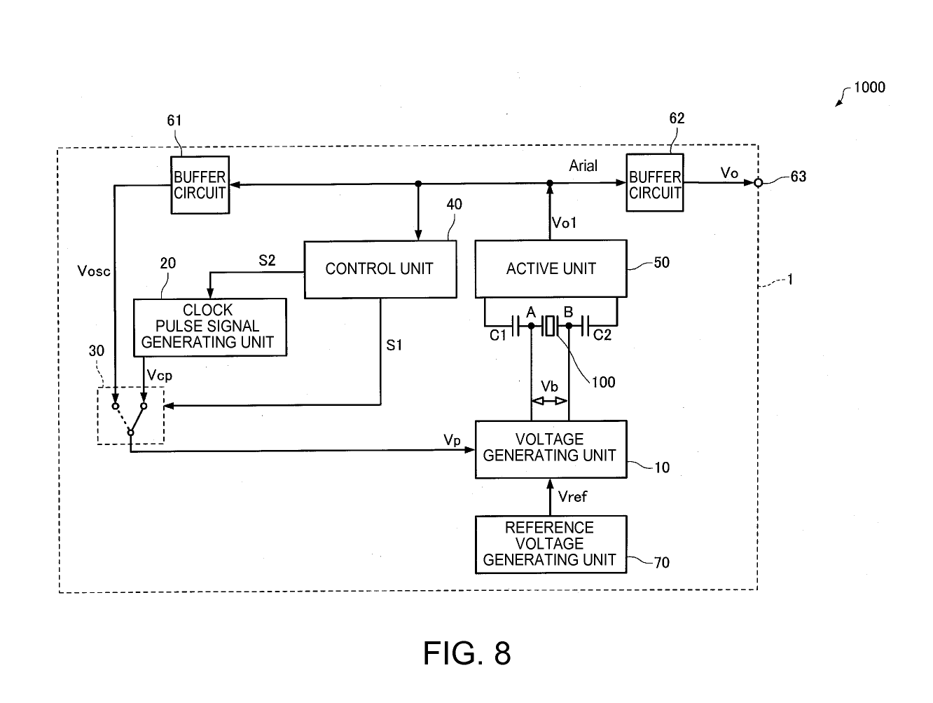

FIG. 8 is a circuit diagram of the oscillator 1000 according to the embodiment. In the example shown in FIG. 8, the oscillator 1000 is configured to include the oscillation circuit 1 according to the first embodiment and the vibrator 100.

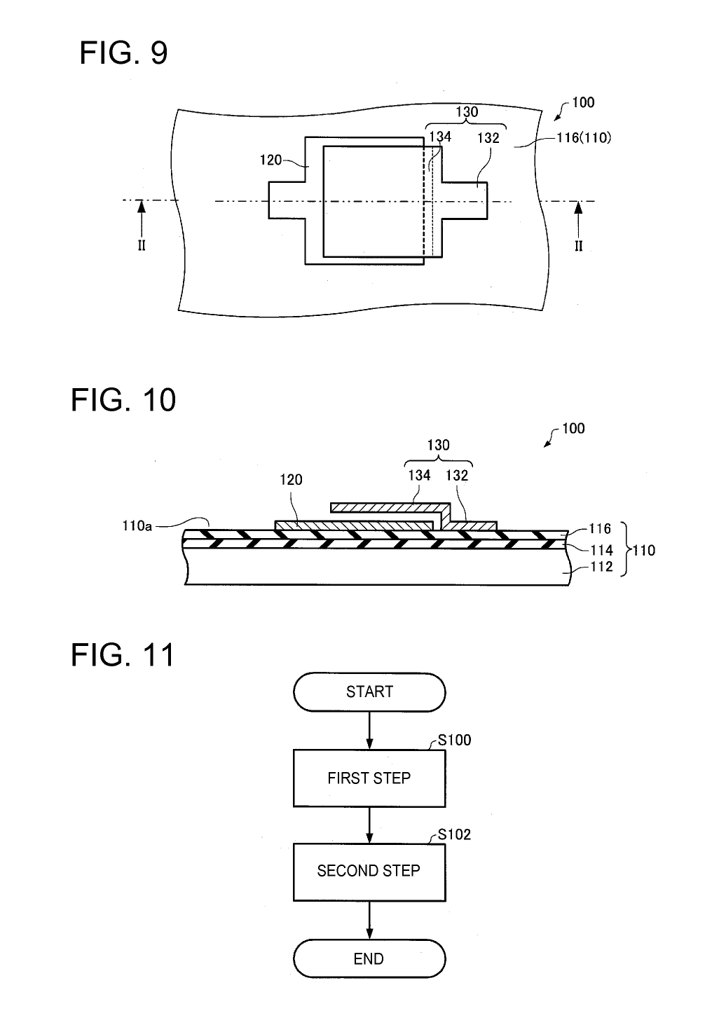

FIG. 9 is a plan view schematically showing a configuration example of the vibrator 100. FIG. 10 is a cross-sectional view schematically showing the configuration example of the vibrator 100, taken along the line II-II in FIG. 9.

It should be noted that, in the descriptions concerning the embodiment, the term “above” may be used, for example, in a manner as “a specific element (hereinafter referred to as “A”) is formed “above” another specific element (hereinafter referred to as “B”).” In the case of such an example, the term “above” is used, while assuming that it includes a case where B is formed directly on A, and a case where B is formed above A through another element.

In the example shown in FIGS. 9 and 10, the vibrator 100 is an electrostatic capacitive MEMS vibrator. As shown in FIGS. 9 and 10, the vibrator 100 is configured to include a first electrode 120 and a second electrode 130 that are provided above a substrate 110.

As shown in FIG. 10, the substrate 110 can include a support substrate 112, a first under layer 114, and a second under layer 116.

As the support substrate 112, for example, a semiconductor substrate such as a silicon substrate can be used. As the support substrate 112, various types of substrates such as a ceramics substrate, a glass substrate, a sapphire substrate, a diamond substrate, or a synthetic resin substrate may be used.

The first under layer 114 is formed above the support substrate 112 (more specifically, on the support substrate 112). As the first under layer 114, for example, a trench insulating layer, a LOCOS (local oxidation of silicon) insulating layer, or a semi-recessed LOCOS insulating layer can be used. The first under layer 114 can electrically isolate the vibrator 100 from other elements (not shown) formed on the support substrate 112.

The second under layer 116 is formed on the first under layer 114. Examples of material of the second under layer 116 include, for example, silicon nitride.

The first electrode 120 of the vibrator 100 is formed on the substrate 110. The shape of the first electrode 120 is, for example, layer-like or thin film-like.

The second electrode 130 of the vibrator 100 is formed spaced apart from the first electrode 120. The second electrode 130 includes a support portion 132 formed on the substrate 110, and a beam portion 134 supported to the support portion 132 and disposed above the first electrode 120. For example, the support portion 132 is disposed facing and spaced from the first electrode 120. The second electrode 130 is formed in a cantilever fashion.

When a voltage is applied between the first electrode 120 and the second electrode 130, the beam portion 134 can vibrate with an electrostatic force occurring between the first electrode 120 and the second electrode 130. That is, the vibrator 100 shown in FIGS. 9 and 10 is an electrostatic capacitive vibrator. The vibrator 100 may include a covering structure to hermetically seal the first electrode 120 and the second electrode 130 in a reduced-pressure state. With this configuration, the air resistance of the beam portion 134 during vibration can be reduced.

Examples of material of the first electrode 120 and the second electrode 130 include, for example, polycrystalline silicon doped with a predetermined impurity to provide conductivity.

The vibrator 100 is not limited to the configuration described above, and various types of publicly known electrostatic capacitive vibrators can be employed. Moreover, any of the voltage generating unit 10, the active unit 50, a reference voltage generating unit 70, the switch unit 30, and the like may be located on the support substrate 112 on which the vibrator 100 is disposed, or all of them may be located on the same support substrate 112.

According to the oscillator 1000 according to the embodiment, since the oscillation circuit 1 capable of performing an oscillating operation even with a low voltage is included, it is possible to realize the oscillator 1000 capable of performing a proper operation even with a low voltage. Also when the oscillation circuit 1a is employed instead of the oscillation circuit 1, a similar advantageous effect is provided for a similar reason. Moreover, also when the voltage generating unit 10a or the voltage generating unit 10b is employed instead of the voltage generating unit 10, a similar advantageous effect is provided for a similar reason.

### 3. Control Method of Oscillator

FIG. 11 is a flowchart showing a control method of an oscillator according to this embodiment. Hereinafter, an example of controlling the oscillator 1000 described above will be described.

The control method of the oscillator 1000 according to the embodiment includes a first step (Step S100) and a second step (Step S102). In the first step (Step S100), in response to the supply of the clock pulse signal Vcp, the input reference voltage Vref is boosted to generate the bias voltage Vb, and the bias voltage Vb is output to the vibrator 100. In the second step (Step S102), in response to the supply of the signal (oscillation signal whose oscillation source is the vibrator 100) Vosc oscillated from the vibrator 100, the reference voltage Vref is boosted to generate the bias voltage Vb, and the bias voltage Vb is output to the vibrator 100.

In the embodiment, in the first step (Step S100), the voltage generating unit 10 boosts, in response to the supply of the clock pulse signal Vcp generated by the clock pulse signal generating unit 20, the reference voltage Vref to generate the bias voltage Vb, and outputs the bias voltage Vb to the vibrator 100 via the switch unit 30 in the first state.

In the embodiment, in the second step (Step S102), the voltage generating unit 10 boosts, in response to the supply of the oscillation signal Vosc whose oscillation source is the vibrator 100, the reference voltage Vref to generate the bias voltage Vb, and outputs the bias voltage Vb to the vibrator 100 via the switch unit 30 in the second state.

Moreover, in the embodiment, the control unit 40 controls the switch unit 30, whereby the second step (Step S102) is performed after the first step (Step S100).

According to the control method of the oscillator 1000 according to the embodiment, since the reference voltage Vref can be boosted with the clock pulse signal Vcp to generate the bias voltage Vb in the first step (Step S100), it is possible to realize the control method of the oscillator 1000 capable of performing an oscillating operation even with a low voltage. Moreover, since the reference voltage Vref can be boosted with the signal (oscillation signal whose oscillation source is the vibrator 100) Vosc oscillated from the vibrator 100 to generate the bias voltage Vb in the second step (Step S102), the degradation of the output signal Vo caused by the intermodulation distortion of the clock pulse signal Vcp and the oscillation signal Vosc (and the oscillation signal Vo1) can be suppressed.

In the second step (Step S102), the clock pulse signal generating unit 20 may stop outputting the clock pulse signal Vcp. In the embodiment, the control unit 40 outputs the control signal S2 to the clock pulse signal generating unit 20 to thereby control the operation of the clock pulse signal generating unit 20 in synchronization with the switch unit 30. With this configuration, the degradation of the output signal Vo caused by the intermodulation distortion of the clock pulse signal Vcp and the oscillation signal Vosc (and the oscillation signal Vo1) can be further suppressed.

### 4. Electronic Apparatus

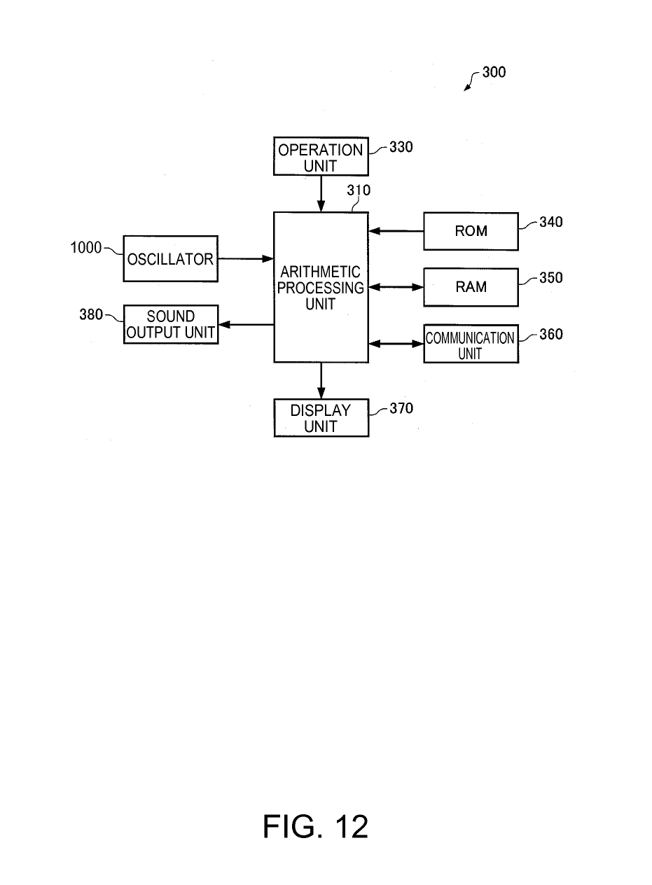

FIG. 12 is a functional block diagram of an electronic apparatus 300 according to this embodiment. Configurations similar to those of the embodiments described above are denoted by the same reference signs and numerals, and a detailed description thereof is omitted.

The electronic apparatus 300 according to the embodiment includes the oscillation circuit 1 or the oscillation circuit 1a. In the example shown in FIG. 12, the electronic apparatus 300 is configured to include the oscillator 1000 configured to include the oscillation circuit 1, an arithmetic processing unit 310, an operation unit 330, a ROM (Read Only Memory) 340, a RAM (Random Access Memory) 350, a communication unit 360, a display unit 370, and a sound output unit 380. The electronic apparatus 300 according to the embodiment may have a configuration in which a portion of the components (parts) shown in FIG. 12 is omitted or changed or another component is added.

The arithmetic processing unit 310 performs various kinds of computing processing or control processing according to programs stored in the ROM 340 or the like. Specifically, the arithmetic processing unit 310 performs, with an output signal of the oscillator 1000 as a clock signal, various kinds of processing according to an operation signal from the operation unit 330, processing for controlling the communication unit 360 for performing data communication with the outside, processing for transmitting a display signal for causing the display unit 370 to display various kinds of information, processing for causing the sound output unit 380 to output various kinds of sounds, and the like.

The operation unit 330 is an input device composed of an operating key, a button switch, and the like, and outputs an operation signal according to a user's operation to the arithmetic processing unit 310.

The ROM 340 stores programs, data, and the like for the arithmetic processing unit 310 to perform various kinds of computing processing or control processing.

The RAM 350 is used as a working area of the arithmetic processing unit 310, and temporarily stores programs or data read from the ROM 340, data input from the operation unit 330, the results of arithmetic operations executed by the arithmetic processing unit 310 according to various kinds of programs, and the like.

The communication unit 360 performs various kinds of controls for establishing data communication between the arithmetic processing unit 310 and an external device.

The display unit 370 is a display device composed of an LCD (Liquid Crystal Display), an electrophoretic display, or the like, and displays various kinds of information based on the display signal input from the arithmetic processing unit 310.

The sound output unit 380 is a device that outputs sounds, such as a speaker.

According to the electronic apparatus 300 according to the embodiment, since the electronic apparatus 300 is configured to include the oscillation circuit 1 capable of performing an oscillating operation even with a low voltage, it is possible to realize the electronic apparatus 300 capable of performing a proper operation even with a low voltage. Also when the electronic apparatus 300 is configured to include the oscillation circuit 1a instead of the oscillation circuit 1, a similar advantageous effect is provided.

As the electronic apparatus 300, various types of electronic apparatuses are considered. For example, examples thereof include personal computers (for example, mobile personal computers, laptop personal computers, and tablet personal computers), mobile terminals such as mobile phones, digital still cameras, inkjet ejection apparatuses (for example, inkjet printers), storage area network apparatuses such as routers or switches, local area network apparatuses, apparatuses for mobile terminal base station, television sets, video camcorders, video recorders, car navigation systems, pagers, electronic notebooks (including those with communication function), electronic dictionaries, calculators, electronic gaming machines, game controllers, word processors, workstations, videophones, surveillance television monitors, electronic binoculars, POS (point of sale) terminals, medical devices (for example, electronic thermometers, sphygmomanometers, blood glucose meters, electrocardiogram measuring systems, ultrasonic diagnosis apparatuses, and electronic endoscopes), fishfinders, various types of measuring instrument, indicators (for example, indicators used in vehicles, aircraft, and ships), flight simulators, head-mounted displays, motion tracing, motion tracking, motion controllers, and PDR (pedestrian dead reckoning).

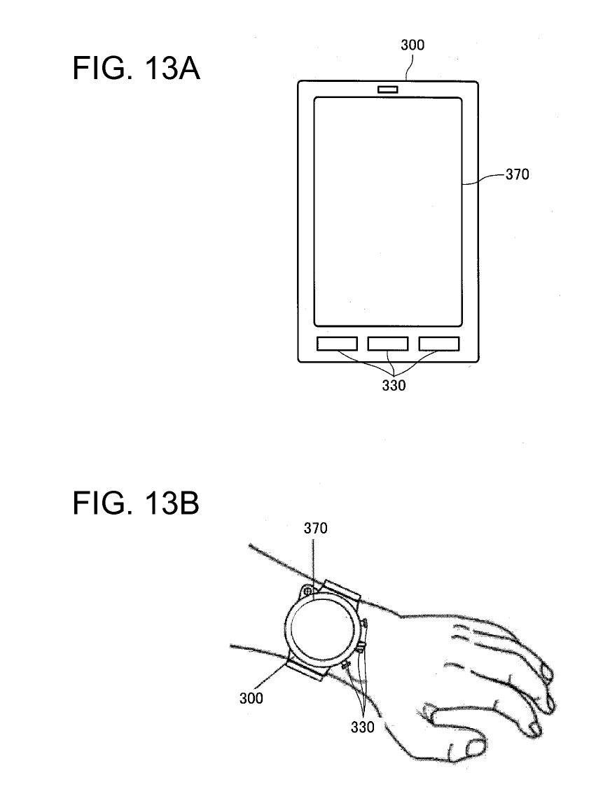

FIG. 13A is a diagram showing an example of the appearance of a smartphone as an example of the electronic apparatus 300. FIG. 13B is a wrist-worn portable device as an example of the electronic apparatus 300. The smartphone as the electronic apparatus 300 shown in FIG. 13A includes buttons as the operation unit 330, and an LCD as the display unit 370. The wrist-worn portable device as the electronic apparatus 300 shown in FIG. 13B includes buttons and a crown as the operation unit 330, and an LCD as the display unit 370. Since the electronic apparatuses 300 are configured to include the oscillation circuit 1 or the oscillation circuit 1a capable of performing an oscillating operation even with a low voltage, it is possible to realize the electronic apparatus 300 capable of performing a proper operation even with a low voltage.

### 5. Moving Object

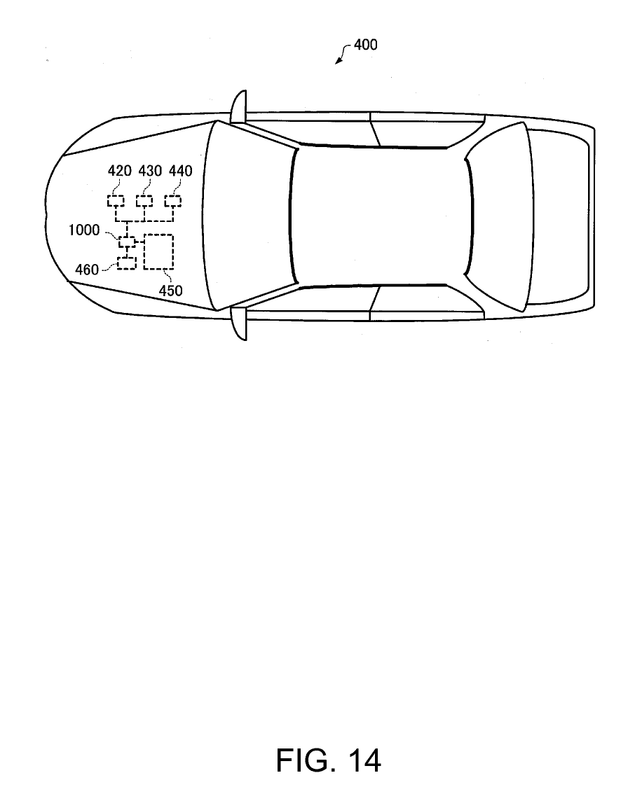

FIG. 14 is a diagram (top view) showing an example of a moving object 400 according to this embodiment. Configurations similar to those of the embodiments described above are denoted by the same reference signs and numerals, and a detailed description thereof is omitted.

The moving object 400 according to the embodiment includes the oscillation circuit 1 or the oscillation circuit 1a. FIG. 14 shows the moving object 400 configured to include the oscillator 1000 configured to include the oscillation circuit 1. In the example shown in FIG. 14, the moving object 400 is configured to include controllers 420, 430, and 440 that perform various kinds of controls for an engine system, a brake system, a keyless entry system, and the like, a battery 450, and a backup battery 460. The moving object 400 according to the embodiment may have a configuration in which a portion of the components (parts) shown in FIG. 14 is omitted or changed or another component is added.

According to the moving object 400 according to the embodiment, since the moving object 400 is configured to include the oscillation circuit 1 capable of performing an oscillating operation even with a low voltage, it is possible to realize the moving object 400 capable of performing a proper operation even with a low voltage. Also when the moving object 400 is configured to include the oscillation circuit 1a instead of the oscillation circuit 1, a similar advantageous effect is provided.

As the moving object 400, various types of moving objects are considered. For example, examples thereof include automobiles (including electric automobiles), aircraft such as jets or helicopters, ships, rockets, and artificial satellites.

Although the embodiments have been described, the invention is not limited to the embodiments but can be implemented in various modes within a range not departing from the gist of the invention.

The invention includes a configuration (for example, a configuration having the same function, method, and result, or a configuration having the same advantage and advantageous effect) that is substantially the same as those described in the embodiments. Moreover, the invention includes a configuration in which a non-essential portion of the configurations described in the embodiments is replaced. Moreover, the invention includes a configuration providing the same operational effects as those described in the embodiments, or a configuration capable of achieving the same advantages. Moreover, the invention includes a configuration in which a publicly known technique is added to the configurations described in the embodiments.

The entire disclosure of Japanese Patent Application No. 2014-075468, filed Apr. 1, 2014 is expressly incorporated by reference herein.

What is claimed is:

1. An oscillation circuit comprising:
a voltage generating unit that includes a booster circuit operating in response to the supply of a pulse signal, and boosts an input reference voltage to generate a bias voltage and outputs the bias voltage to a vibrator;
a clock pulse signal generating unit that generates and outputs a clock pulse signal; and
a switch unit that switches its state between a first state in which the pulse signal to be input to the booster circuit is set to the clock pulse signal and a second state in which the pulse signal is set to a signal oscillated from the vibrator.

2. The oscillation circuit according to claim 1, wherein the clock pulse signal generating unit stops outputting the clock pulse signal when the switch unit is in the second state.

3. The oscillation circuit according to claim 1, wherein the switch unit switches the state from the first state to the second state.

4. The oscillation circuit according to claim 1, wherein the switch unit is in the first state upon initial energization.

5. The oscillation circuit according to claim 1, wherein the switch unit switches the state from the first state to the second state when the voltage amplitude of the oscillation signal is equal to or greater than a reference value.

6. The oscillation circuit according to claim 1, wherein the switch unit switches the state from the first state to the second state when an elapsed time since initial energization is equal to or greater than a reference time.

7. The oscillation circuit according to claim 1, further comprising a frequency dividing circuit that divides the frequency of a signal whose oscillation source is the vibrator to output the oscillation signal.

8. The oscillation circuit according to claim 1, wherein the voltage generating unit includes a voltage adjusting circuit that converts an input or output voltage of the booster circuit into a voltage having a given magnitude and outputs the voltage.

9. The oscillation circuit according to claim 1, wherein the vibrator is an electrostatic capacitive MEMS vibrator.

10. An oscillator comprising:
the oscillation circuit according to claim 1; and
the vibrator.

11. An electronic apparatus comprising the oscillation circuit according to claim 1.

12. A moving object comprising the oscillation circuit according to claim 1.

13. A control method of an oscillator, comprising:
boosting, in response to the supply of a clock pulse signal, an input reference voltage to generate a bias voltage and outputting the bias voltage to a vibrator; and
boosting, in response to the supply of a signal oscillated from the vibrator, the reference voltage to generate the bias voltage and outputting the bias voltage to the vibrator.
